(19) United States
(12) Patent Application Publication
(10) Pub. No.: US 2023/0180544 A1
(43) Pub. Date: Jun. 8, 2023

(54) DISPLAY PANEL AND DISPLAY DEVICE INCLUDING THE SAME

(71) Applicant: LG Display Co., Ltd., Seoul (KR)

(72) Inventors: Minkuk KIM, Paju-si (KR); Youngjin KIM, Paju-si (KR)

(21) Appl. No.: 18/057,704

(22) Filed: Nov. 21, 2022

(30) Foreign Application Priority Data
Dec. 2, 2021 (KR) 10-2021-0171035

(51) Int. Cl. H01L 27/32; H01L 51/52

(52) U.S. Cl. CPC H01L 27/3272; H01L 51/529

(57) ABSTRACT

A display panel capable of improving a discharge path of static electricity to reduce image defect, and a display device including the same are disclosed. The display panel includes a display area where pixels are disposed and a discharge area surrounding the edge of the display area. The display panel includes: an outline wire extending along the discharge area; and a wire branch disposed in the discharge area and extending from at least one portion of the outline wire to an end of the display panel.

### CROSS-REFERENCE TO RELATED APPLICATION

This application claims priority to and benefit of Korean Patent Application No. 10-2021-0171035, filed 02 Dec. 2021, which is hereby incorporated by reference as when fully set forth herein.

### BACKGROUND

### Technical Field

The present disclosure relates to a display device, and more particularly, to a display panel which may improve a discharge path of static electricity to reduce an image defect, and a display device including the same.

### Description of Related Art

Contents described in this Background section simply provide background information about the present disclosure and do not constitute the prior art

As we enter the information age, a display device that visually displays electrical information signals is developing rapidly. Research to develop thinner and lighter display devices having lower power consumption and reliable performance is continuing.

Representative display devices include a liquid crystal display device (LCD), and an organic light-emitting display device (OLED).

The organic light-emitting display device is a self-emissive display device. Unlike the liquid crystal display device, the OLED does not require a separate light source, and thus may be manufactured in a lightweight and thin form. Further, the organic light-emitting display device is not only advantageous in terms of power consumption due to its low-voltage operation, but also has excellent color rendering, a fast response speed, a wide viewing-angle, and a high contrast ratio, and thus may be expected to be used in various fields.

### BRIEF SUMMARY

As the display device becomes smaller, efforts are being made to reduce a bezel area thereof which is an outer edge outside a display area, in order to increase an active display screen size in the same area of the display device.

Further, a cover glass to protect the display device is exposed to an outside. Thus, friction thereof with external materials may occur frequently. Thus, the cover glass generates static electricity due to the friction, and the static electricity may flow into an inside of a display panel. This eventually causes damage to pixels of the display panel, resulting in an image defect.

Accordingly, the inventors of the present disclosure have recognized the above-mentioned problem and thus have invented a display device that improves discharge performance for effectively discharging friction based static electricity to improve image reliability.

One or more embodiments of the present disclosure provide a display panel capable of improving a discharge path of static electricity to reduce an image defect, and a display device including the same.

A display panel according to an embodiment of the present disclosure includes a display area in which pixels are disposed, and a discharge area surrounding an edge of the display area. In the discharge area, an outline wire extends along the discharge area, and at least one area of the outline wire includes a wire branch extending to an end of the panel.

A display device according to an embodiment of the present disclosure includes a display panel, a cover glass disposed on a front face of the display panel, a heat dissipation layer disposed on a back face of the display panel, and a static electricity discharge member coated on the cover glass and extending to a side of the display panel. The display panel includes a display area where pixels are disposed and a discharge area surrounding an edge of the display area, wherein an outline wire extends along the discharge area, and at least one area of the outline wire includes a wire branch extending to an end of the display panel.

The display panel and the display device including the same according to an embodiment of the present disclosure may improve the discharge path of static electricity to reduce an image defect such as a green tint.

Further, in the display panel and the display device including the same according to one embodiment of the present disclosure, the outline wire extending along and on an outer portion of the panel may extend to an end of the panel, thereby reducing opening defect of the discharge path.

Further, the display panel and the display device including the same according to one embodiment of the present disclosure may reduce a discharge path length to facilitate static electricity discharge.

Further, the display panel and the display device including the same according to one embodiment of the present disclosure may reduce a used amount of a coating solution due to the shortened discharge path, thereby reducing an overflow.

Further, the display panel and the display device including the same according to an embodiment of the present disclosure may effectively discharge static electricity based on friction, thereby reducing or minimizing damage to the display panel.

Further, the display panel and the display device including the same according to an embodiment of the present disclosure may block inflow of external static electricity therein to reduce or minimize deterioration of image quality.

Effects of the present disclosure are not limited to the above-mentioned effects, and other effects as not mentioned will be clearly understood by those skilled in the art from following descriptions.

The purposes, solutions, and effects of the disclosure as described above does not specify essential features of claims. Thus, the scope of claims is not limited by the purposes, solutions, and effects of the disclosure as described above.

### BRIEF DESCRIPTION OF THE SEVERAL VIEWS OF THE DRAWINGS

FIG. 1 is a plan view of a display panel according to a first embodiment and a display device including the same.

FIG. 2 is a cross-sectional view taken along a line I-I′ in FIG. 1.

FIG. 3 is a cross-sectional view showing opening defect in a cross-sectional view taken along a line I-I′ in FIG. 1.

FIG. 4 is a plan view illustrating a display panel according to a second embodiment and a display device including the same.

FIG. 5 is a cross-sectional view taken along a line I-I′ in FIG. 4.

FIG. 6 shows a wire branch according to a first example extending from a branched portion EA of FIG. 4.

FIG. 7 shows a wire branch according to a second example extending from the branched portion EA of FIG. 4.

FIG. 8 shows a wire branch according to a third example extending from the branched portion EA of FIG. 4.

FIG. 9 shows a wire branch according to a fourth example extending from the branched portion EA of FIG. 4.

FIG. 10 is a plan view of a display panel according to a third embodiment and a display device including the same.

FIG. 11 is a plan view of a display panel according to a fourth embodiment and a display device including the same.

### DETAILED DESCRIPTIONS

Advantages and features of the present disclosure, and how to achieve them will become apparent with reference to the embodiments described below in detail in conjunction with the accompanying drawings. However, the present disclosure is not limited to the embodiments as disclosed below, but will be implemented in a variety of different forms. Only these embodiments make the present disclosure complete, and are constructed to fully inform those having common knowledge in the technical field to which the present disclosure belongs of a scope of the disclosure.

A shape, a size, a dimension (e.g., length, width, height, thickness, radius, diameter, area, etc.), a ratio, an angle, a number of elements, etc., disclosed in the drawings for illustrating embodiments of the present disclosure are examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location and thickness of the components illustrated in various drawings submitted herewith are part of the present disclosure.

The same reference numerals refer to the same elements herein. Further, in describing the present disclosure, when it is determined that a detailed description of a related known element may unnecessarily obscure gist of the present disclosure, the detailed description thereof will be omitted. As used herein, the singular forms “a” and “an” are intended to include the plural forms as well, unless the context clearly indicates otherwise. It will be further understood that the terms “comprises,” “comprising,” “includes,” and “including” when used in this specification, specify the presence of the stated features, integers, operations, elements, and/or components, but do not preclude the presence or addition of one or more other features, integers, operations, elements, components, and/or portions thereof.

In interpreting a numerical value, the value is interpreted as including an error range unless there is no separate explicit description thereof.

It will be understood that when an element or layer is referred to as being “connected to,” or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present. In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after,” “subsequent to,” “before,” etc., another event may occur therebetween unless “directly after,” “directly subsequent” or “directly before” is not indicated.

It will be understood that, although the terms “first,” “second,” “third,” and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or entirely combined with each other, and may be technically associated with each other or operate with each other. The embodiments may be implemented independently of each other and may be implemented together in an association relationship.

In descriptions of temporal relationships, for example, temporal precedent relationships between two events such as “after,” “subsequent to,” “before,” etc., another event may occur therebetween unless “directly after,” “directly subsequent” or “directly before” is not indicated. The features of the various embodiments of the present disclosure may be partially or entirely combined with each other, and may be technically associated with each other or operate with each other. The embodiments may be implemented independently of each other and may be implemented together in an association relationship. Spatially relative terms, such as “beneath,” “below,” “lower,” “under,” “above,” “upper,” and the like, may be used herein for ease of explanation to describe one element or feature’s relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented for example, rotated 90 degrees or at other orientations, and the spatially relative descriptors used herein should be interpreted accordingly.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display panel according to some embodiments and a display device including the same will be described.

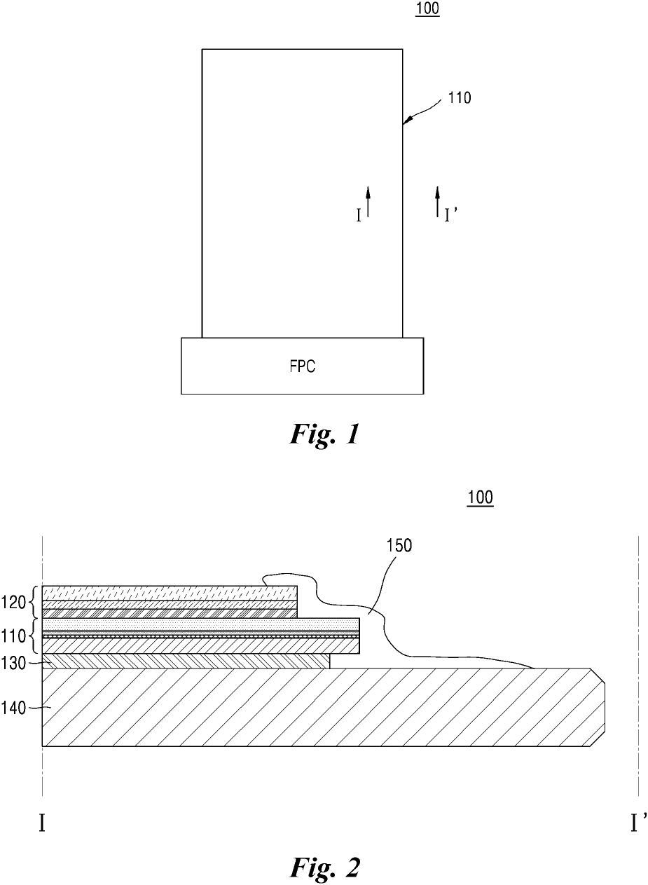

FIG. 1 is a plan view of a display panel 110 according to a first embodiment and a display device 100 including the same. FIG. 2 is a cross-sectional view taken along a line I-I′ in FIG. 1.

Referring to FIG. 1 and FIG. 2, the display device 100 according to the first embodiment includes the display panel 110 and a flexible printed circuit FPC on which a driver circuit that drives the display panel 110 is mounted.

The display panel 110 may include a display area. A plurality of pixels may be disposed in the display area.

In one example, in the display panel 110, pixels may be respectively disposed in areas where a plurality of gate lines and a plurality of data lines intersect each other. Each pixel may include an organic light-emitting diode (OLED), and a pixel circuit that supplies a driving current to the organic light-emitting diode.

The pixel circuit may receive a source signal from a source driver and generate the driving current based on the source signal, and may supply the driving current to the organic light-emitting diode such that the organic light-emitting diode emits light.

The source driver, a gate driver, and a timing controller may be mounted on the flexible printed circuit FPC. In one example, the flexible printed circuit FPC may be bent toward a back face of the display panel 110.

The timing controller may provide a control signal for controlling an operation timing to each of the gate driver and the source driver, and may provide an image signal to the source driver.

The source driver may sample and latch an image signal and output a gamma voltage corresponding to the image signal to a data line of the display panel 110 as the source signal.

The gate driver may output a gate signal obtained by level-shifting a gate voltage to a gate line of the display panel 110.

Referring to FIG. 2, the display device 100 according to the first embodiment includes the display panel 110, a cover glass 140, a heat dissipation layer 120, and a static electricity discharge member 150.

The display panel 110 is formed between the cover glass 140 and the heat dissipation layer 120. In one example, the display panel 110 may include a BP (Back Plate) layer. A TOE (Touch On Encapsulation) layer may be formed under the BP layer, and a POL (Polarizing Film) layer may be formed under the TOE layer.

The heat dissipation layer 120 is formed on a back face of the display panel 110. In one example, the heat dissipation layer 120 may include a conductive layer. A foam layer may be formed under the conductive layer, and an embossed layer may be formed under the foam layer.

The conductive layer may be made of a material having excellent thermal conductivity, electrical conductivity, and mechanical rigidity. In one example, the conductive layer may be made of copper (Cu) or stainless steel (SUS).

This heat dissipation layer 120 may serve to dissipate heat generated from the display panel 110. The heat dissipation layer 120 may serve to ground the static electricity discharge member 150 which will be described later. Further, the heat dissipation layer 120 may serve to block an impact from the back face of the display device 100.

The cover glass 140 is formed on a front face of the display panel 110. In one example, the cover glass 140 may be formed to cover a front face of the display panel 110, and may be formed in a larger area than that of the front face of the display panel 110. This cover glass 140 may be constructed to cover the front face of the display panel 110 and may serve to protect the display panel 110.

An adhesive layer 130 may be further formed between the cover glass 140 and the display panel 110. In one example, the adhesive layer 130 may include OCA (Optically Clear Adhesive).

The static electricity discharge member 150 may be formed by coating a conductive polymer compound on a side face of the display panel 100, a side face of the heat dissipation layer 120, a side face of the adhesive layer 130, and a top of the cover glass 140. In one example, the static electricity discharge member 150 may be embodied as a coated layer made of a conductive polymer compound.

The static electricity discharge member 150 may serve to discharge static electricity through the heat dissipation layer 120 when the static electricity is generated from the cover glass 140.

In one example, the static electricity discharge member 150 may reduce an electric field between the cover glass 140 and the heat dissipation layer 120 by moving electric charges of the cover glass 140 to a ground terminal of the heat dissipation layer 120.

Thus, the display device according to the embodiment may reduce image quality defect such as green tint caused by the static electricity.

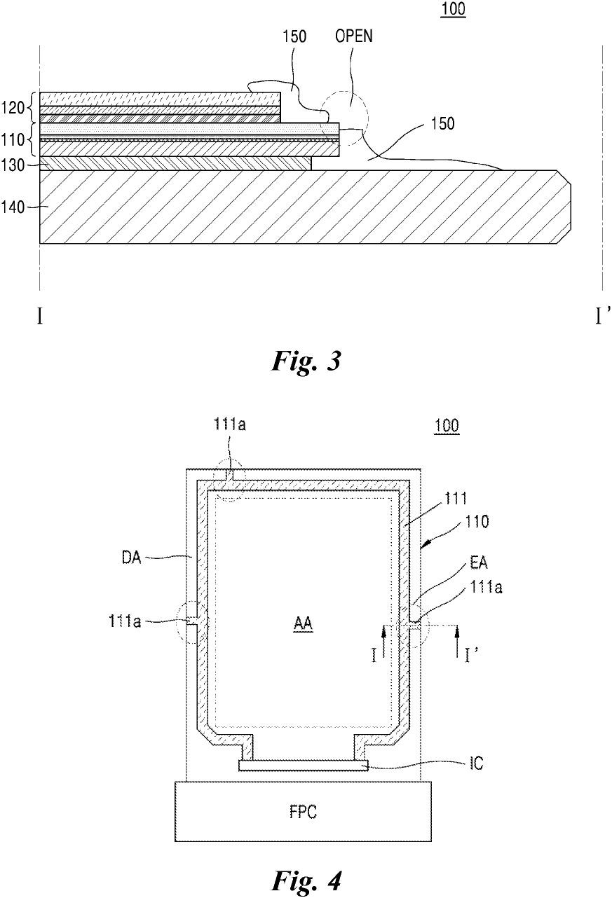

FIG. 3 is a cross-sectional view showing opening defect in a cross-sectional view taken along a line I-I′ in FIG. 1.

Referring to FIG. 3, the static electricity discharge member 150 between the cover glass 140 and the heat dissipation layer 120 may be embodied as a coated layer. Thus, the static electricity discharge member 150 may be discontinuous due to a stack step portion and a handling operation.

When the coated layer is discontinuous, an electric field between the cover glass 140 and the heat dissipation layer 120 may increase. The increased electric field between the cover glass 140 and the heat dissipation layer 120 causes the green tint.

Accordingly, the display device that reduces the opening defect of the static electricity discharge member 150 due to the stack step portion and the handling operation is disclosed.

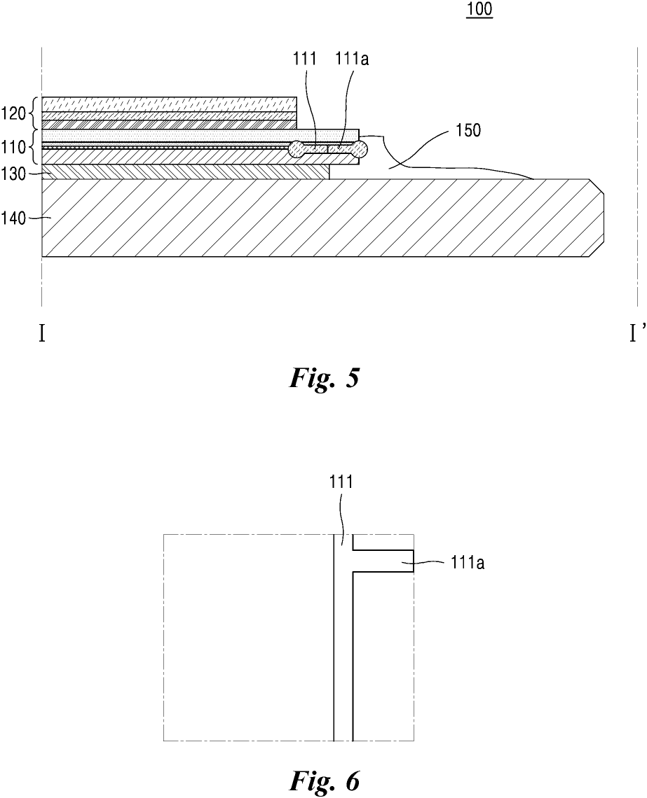

FIG. 4 is a plan view of the display panel 110 according to a second embodiment and the display device 100 including the same. FIG. 5 is a cross-sectional view taken along a line I-I′ in FIG. 4.

Referring to FIG. 4 and FIG. 5, the display device 100 according to the second embodiment includes the display panel 110 and the flexible printed circuit FPC in which the driver circuit that drives the display panel 110 is mounted.

The display panel 110 may be divided into a display area AA where pixels are disposed and a discharge area DA surrounding an edge of the display area AA. In the discharge area DA, an outline wire 111 may extend along the discharge area DA. The outline wire 111 may include a wire branch 111a extending to an end of the display panel 110 in at least one area EA.

The wire branch 111a may be connected to the static electricity discharge member 150 coated on a side face of the display panel 110. In one example, the wire branch 111a may refer to a wire extending from the branched portion EA of the outline wire 111 to an end of the display panel 110.

In another example, the wire branch 111a may include at least two or more wires extending from the branched portion EA of the outline wire 111 to an end of the display panel 110.

In another example, the wire branch 111 may extend from the branched portion EA of the outline wire 111 to an end of the display panel 110 and may have a larger width than that of the outline wire 111.

The outline wire 111 may be connected to the ground terminal. In one example, the outline wire 111 may be connected to the ground terminal through an internal circuit IC of the display device 100.

In one example, the outline wire 111 may be connected to the ground terminal through a crack detection circuit that detects a crack of the display panel 110. In another example, the outline wire 111 may be connected to the ground terminal of the source driver or the gate driver mounted on the flexible printed circuit FPC.

In one example, in the second embodiment of FIG. 4, the outline wire 111 is illustrated as being connected to the internal circuit IC of the display device 100. However, the disclosure is not limited thereto. In another example, the outline wire 111 may be connected directly to the ground terminal. Alternatively, the outline wire 111 may be connected to the heat dissipation layer 120. Alternatively, the outline wire 111 may be connected to the ground terminal through the heat dissipation layer 120 and the internal circuit IC.

Referring to FIG. 5, the display device 100 according to the second embodiment includes the display panel 110, the cover glass 140, the heat dissipation layer 120, and the static electricity discharge member 150.

The cover glass 140 may be formed on the front face of the display panel 110. In this regard, the front face may be defined as a face thereof on which pixels are disposed to display an image. In one example, the cover glass 140 may be formed to cover the front face of the display panel 110, and may be formed in a larger area than that of the front face of the display panel 110. This cover glass 140 may cover the front face of the display panel 110 and may serve to protect the display panel 110.

The display panel 110 may be formed on the cover glass 140. In one example, the display panel 110 may include the BP (Back Plate) layer. The TOE (Touch On Encapsulation) layer may be formed under the BP layer, and the POL (Polarizing Film) layer may be formed under the TOE layer.

Moreover, the adhesive layer 130 may be further formed between the display panel 110 and the cover glass 140. In one example, the adhesive layer 130 may include OCA (Optically Clear Adhesive).

The heat dissipation layer 120 is formed on the back face of the display panel 110. In this regard, the back face may be defined as a face thereof opposite to the front face where the image is displayed. In one example, the heat dissipation layer 120 may include a conductive layer. A foam layer may be formed under the conductive layer, and an embossed layer may be formed under the foam layer.

In one example, the conductive layer may be made of a material having excellent thermal conductivity, electrical conductivity and mechanical rigidity. The conductive layer may be composed of copper (Cu) or stainless steel (SUS).

This heat dissipation layer 120 may serve to dissipate heat generated from the display panel 110. Further, the heat dissipation layer 120 may serve to block the impact from the back face of the display device 100.

The static electricity discharge member 150 may be coated on a top of the cover glass 140a and the side face of the display panel 110 on the cover glass.

In an embodiment, the static electricity discharge member 150 may be embodied as a coated layer made of a conductive polymer compound. The static electricity discharge member 150 may serve to discharge static electricity through the wire branch 111a and the outline wire 111 when the static electricity is generated from the cover glass 140. In one example, the static electricity discharge member 150 may reduce the electric field between the cover glass 140 and the display panel 110 by moving the electric charges of the cover glass 140 to the ground terminal through the wire branch 111a and the outline wire 111.

Thus, the static electricity discharge member 150, the wire branch 111a, and the outline wire 111 may constitute a discharge path for discharging the static electricity.

The display panel 110 and the display device 100 including the same according to the second embodiment may include the at least one wire branch 111a from a portion of the outline wire 111 extending along and on an outer portion of the display panel 110 to an end of the display panel 110, thereby reducing the opening defect of the static electricity discharge member 150 due to the step portion and the handling.

Further, the display panel 110 and the display device 100 including the same according to the second embodiment may reduce the length of the discharge path from the cover glass 140 to the side face of the display panel 110 to facilitate static electricity discharge. Due to the shortened discharge path, an amount of the coated static electricity discharge member 150 is reduced. Thus, overflow of the coating solution may be suppressed.

FIG. 6 shows the wire branch 111a according to a first example extending from the branched portion EA of FIG. 4. Referring to FIG. 6, the wire branch 111a according to the first example may include one wire extending from the branched portion EA of the outline wire 111 to an end of the display panel 110.

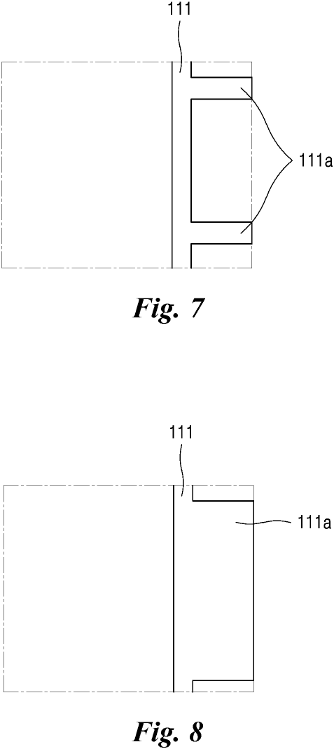

FIG. 7 shows the wire branch 111a according to a second example extending from the branched portion EA of FIG. 4. Referring to FIG. 7, the wire branch 111a according to the second example may include two wires extending from the branched portion EA of the outline wire 111 to an end of the display panel 110.

FIG. 8 shows the wire branch 111a according to a third example extending from the branched portion EA of FIG. 4. Referring to FIG. 8, the wire branch 111a according to the third example may extend from the branched portion EA of the outline wire 111 to an end of the display panel 110 and may have a larger width than that of the outline wire 111.

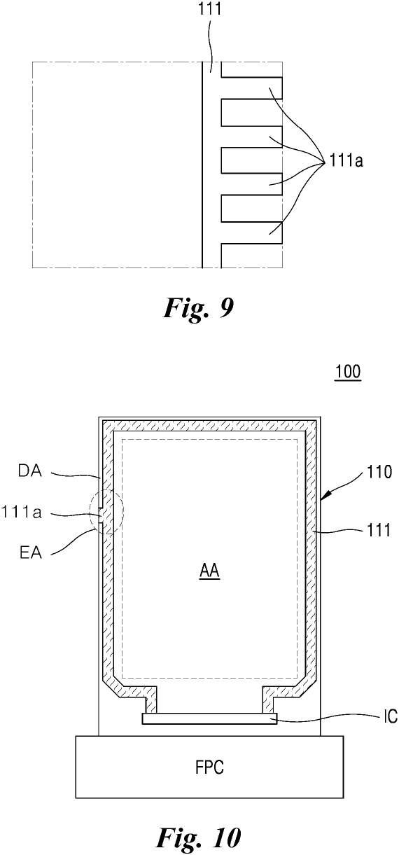

FIG. 9 shows the wire branch 111a according to a fourth example extending from the branched portion EA of FIG. 4. Referring to FIG. 9, the wire branch 111a according to the fourth example may include four wires extending from the branched portion EA of the outline wire 111 to an end of the display panel 110.

This wire branch 111a may be modified as long as the branch 111 a includes at least one wire extending from the branched portion EA of the outline wire 111 extending along the discharge area DA surrounding the edge of the display area AA to the end of the display panel 110.

Further, the wire branch 111a may have a width equal to or greater than that of the outline wire 111.

This wire branch 111a is electrically connected to the static electricity discharge member 150 coated on the side face of the display panel 110.

In one example, the display device according to the second embodiment includes the branched portion EA on a left edge, a right edge, and/or a top edge of the display panel 110. However, the disclosure is not limited thereto.

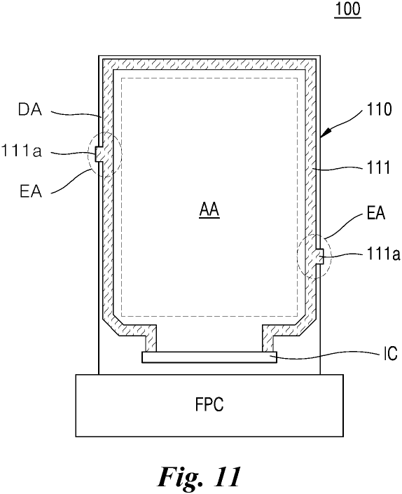

FIG. 10 is a plan view of a display panel according to a third embodiment and a display device including the same. FIG. 11 is a plan view of a display panel according to a fourth embodiment and a display device including the same.

As shown in FIG. 10, the branched portion EA may be formed on the left edge of the display panel 110. Alternatively, as shown in FIG. 11, the branched portion EA may be formed on each of the left edge and the right edge of the display panel 110.

The location of the wire branch 111a may vary as long as the display device 100 according to the embodiments has a static electricity discharge path extending from the static electricity discharge member 150 coated on the side face of the display panel 110 to the wire branch 111a and the outline wire 111.

In one example, when static electricity is introduced from the cover glass 140 to the display device 100, the device 100 may discharge the static electricity to the ground terminal via the static electricity discharge member 150, the wire branch 111a, and the outline wire 111.

As described above, the display panel 110 according to the embodiment and the display device 100 including the same may improve the discharge path of the static electricity to reduce the image defect such as green tint.

Further, in the display panel 110 according to the embodiment and the display device 100 including the same, the outline wire 111 extending on and along the outer portion of the panel may branch to the end of the panel, thereby reducing the opening defect of the discharge path.

Further, the display panel 110 according to the embodiment and the display device 100 including the same may reduce the discharge path length to facilitate static electricity discharge.

Further, the display panel 110 according to the embodiment and the display device 100 including the same may reduce the used amount of the coating solution due to the shortened discharge path, thereby suppressing the overflow of the solution.

Further, the display panel 110 according to the embodiment and the display device 100 including the same may effectively discharge the static electricity due to friction, thereby reducing or minimizing damage to the display panel 110.

Further, the display panel 110 according to the embodiment and the display device 100 including the same may block the inflow of external static electricity thereto to reduce or minimize the deterioration of image quality.

The display panel 110 according to an embodiment of the present disclosure includes the display area AA in which pixels are disposed, and the discharge area DA surrounding an edge of the display area AA. In the discharge area DA, the outline wire 111 extends along the discharge area DA, and at least one area of the outline wire 111 includes the wire branch 111a therefrom extending to an end of the panel 110.

The wire branch 111a is connected to the static electricity discharge member 150 coated on the side face of the display panel 110.

The static electricity discharge member 150 is coated on a top face of the cover glass 140 disposed on a front face of the display panel 110 and on the side face of the display panel 110. In one example, the static electricity discharge member 150 may be formed by coating the conductive polymer compound on the side face of the display panel 100, on the side face of the adhesive layer 130 and the top face of the cover glass 140.

The wire branch 111a, the static electricity discharge member 150, and the outline wire 111 may constitute a discharge path to discharge the static electricity generated from the cover glass 140.

The wire branch 111a may include one or more wires that extend to the end of the display panel 110.

The wire branch 111a is wider than the outline wire 111 and extends to the end of the display panel 110.

The outline wire 111 is connected to the ground terminal.

The outline wire 111 is connected to the ground terminal via the crack detection circuit that detects the crack of the display panel 110.

The outline wire 111 is connected to the ground terminal via the source driver or the gate driver that operates the display panel 110.

The display device 100 according to an embodiment of the present disclosure includes the display panel 110, the cover glass 140 disposed on a front face of the display panel 110, the heat dissipation layer 120 disposed on a back face of the display panel 110, and the static electricity discharge member 150 coated on the side face of the display panel 110 and on a top face of the cover glass 140.

The display panel 110 includes the display area AA where pixels are disposed and the discharge area DA surrounding the edge of the display area. The wire 111 extends along the discharge area DA, and at least one area of the outline wire 111 includes a wire branch 111a extending to an end of the display panel 110.

In one example, in the display panel 110 according to the first embodiment and the display device 100 including the same, the static electricity discharge member 150 is coated on the top face of the cover glass 140, on the side face of the display panel 110 and on the side face of the heat dissipation layer 120.

Moreover, the display panel 110 according to each of the second to fourth embodiments and the display device 100 including the same, the static electricity discharge member 150 is coated on a top face of the cover glass 140, and on the side face of the display panel 110. The at least one wire branch 111a extending from the outline wire 111 of the display panel 110 to the end of the display panel 110 is connected to the static electricity discharge member 150.

Although not shown, the display panel 110 according to a fifth embodiment and the display device 100 including the same may include all the features of the first to fourth embodiments.

The display panel 110 according to the fifth embodiment and the display device 100 including the same may include the static electricity discharge member 150 coated on the top face of the cover glass 140 and on the side face of the display panel 110 and the side face of the heat dissipation layer 120, wherein at least one wire branch 111a may extend from a portion of the outline wire 111 of the display panel 110 to an end of the display panel 110 and may be connected to the static electricity discharge member 150.

The present disclosure as described above is not limited to the above-described embodiments and the accompanying drawings. It will be apparent to those of ordinary skill in the technical field to which the present disclosure belongs that various substitutions, modifications and changes may be made within the scope not departing from the technical ideas of the present disclosure. Therefore, the scope of the present disclosure includes the following claims, and all changes or modifications derived from the meaning and scope of the claims and their equivalent concepts should be construed as being included in the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display panel, comprising:
a display area where pixels are disposed; and
a discharge area adjacent to the display area,
wherein the display panel includes:
an outline wire extending along the discharge area; and
a wire branch disposed in the discharge area and extending from at least one portion of the outline wire to an end of the display panel.

2. The display panel of claim 1, wherein the display panel includes a static electricity discharge member coated on a side face of the display panel, wherein the wire branch is coupled to the static electricity discharge member.

3. The display panel of claim 2, wherein the static electricity discharge member is coated on a top face of the cover glass disposed on a front face of the display panel and on a side face of the display panel.

4. The display panel of claim 3, wherein the static electricity discharge member, the wire branch, and the outline wire constitute a discharge path to discharge static electricity generated from the cover glass.

5. The display panel of claim 1, wherein the wire branch is divided into at least one wire extending to the end of the display panel.

6. The display panel of claim 1, wherein a width of the wire branch is greater than a width of the outline wire.

7. The display panel of claim 1, wherein the outline wire is coupled to a ground terminal.

8. The display panel of claim 7, wherein the outline wire is coupled to the ground terminal via a crack detection circuit for detecting cracks in the display panel.

9. The display panel of claim 7, wherein the outline wire is coupled to the ground terminal via a source driver or a gate driver for driving the display panel.

10. A display device, comprising:
a display panel;
a cover glass disposed on a front face of the display panel;
a heat dissipation layer disposed on a back face of the display panel; and
a static electricity discharge member coated on a top face of the cover glass, and on a side face of the display panel,
wherein the display panel includes:
a display area where pixels are disposed;
a discharge area adjacent to the display area;
an outline wire extending along the discharge area; and
a wire branch disposed in the discharge area and extending from at least one portion of the outline wire to an end of the display panel.

11. The display device of claim 10, wherein the wire branch is coupled to a portion of the static electricity discharge member coated on the side face of the display panel.

12. The display device of claim 10, wherein the wire branch, the static electricity discharge member, and the outline wire constitute a discharge path to discharge static electricity generated from the cover glass.

13. The display device of claim 10, wherein the wire branch is divided into at least one wire extending to the end of the display panel.

14. The display device of claim 10, wherein the wire branch has a width greater than a width of the outline wire.

15. The display device of claim 10, wherein the outline wire is coupled to a ground terminal.

16. The display device of claim 15, wherein the outline wire is coupled to the ground terminal via a crack detection circuit for detecting a crack of the display panel.

17. The display device of claim 15, wherein the outline wire is coupled to the ground terminal via a source driver or a gate driver for driving the display panel.
